(19) United States
(12) Patent Application Publication
(10) Pub. No.: US 2016/0267014 A1
(43) Pub. Date: Sep. 15, 2016

(54) STORAGE APPARATUS, STORAGE APPARATUS CONTROL METHOD, AND INFORMATION PROCESSING SYSTEM

(71) Applicant: FUJITSU LIMITED, Kawasaki-shi (JP)

(72) Inventor: Yoshiyasu DOI, Munich (DE)

(73) Assignee: FUJITSU LIMITED, Kawasaki-shi (JP)

(21) Appl. No.: 15/016,817

(22) Filed: Feb. 5, 2016

(30) Foreign Application Priority Data
Mar. 13, 2015 (JP) 2015-050973

(51) Int. Cl. G06F 12/10; G11C 13/00

(52) U.S. Cl. CPC G06F 12/109; G11C 13/0069; G06F 2212/657

(57) ABSTRACT

A storage apparatus includes a physical memory including a plurality of first memory lines a part of which are assigned consecutive addresses and the rest of which are put into an unassigned state where no address is assigned and a second memory line assigned one of the consecutive addresses. The storage apparatus determines based on an address whether a write access to the physical memory is a write access to a first memory line or the second memory line, counts the numbers of times the first memory lines are written and the number of times the second memory line is written, and uses, when the total sum of the counted numbers of times exceeds a threshold, a first memory line in the unassigned state for swapping the address assigned to the second memory line with one of the addresses assigned to the part of the first memory lines.

### CROSS-REFERENCE TO RELATED APPLICATION

This application is based upon and claims the benefit of priority of the prior Japanese Patent Application No. 2015-050973, filed on Mar. 13, 2015, the entire contents of which are incorporated herein by reference.

### FIELD

The embodiments discussed herein are related to a storage apparatus, a storage apparatus control method, and an information processing system.

### BACKGROUND

In the field of information processing, nonvolatile memories which continue holding stored contents even in the case of power supply being stopped are used in various situations. NAND flash memories are widely used as nonvolatile memories. Furthermore, high performance nonvolatile memories, such as a resistance random access memory (ReRAM), a phase change memory (PCM), and a spin transfer torque (STT)-magnetoresistive random access memory (MRAM), have recently been developed.

Nonvolatile memories have the following property. When the same memory line (block having a size of 16 KB, 128 KB, or the like) is written repeatedly, reading or writing becomes impossible due to degradation of memory cells. Accordingly, the following technique which is referred to as wear leveling is proposed. With this technique, write destinations are distributed within each chip including a plurality of memory lines or each module including a plurality of chips so that a specific memory line will not be written intensively. By doing so, the degree to which each memory line is consumed is equalized.

For example, table-based wear leveling (hereinafter referred to as the TB method) is proposed. With the TB method wear leveling is realized by the use of a conversion table in which a physical address for specifying a memory line is associated with a logical address for specifying a write destination.

With the TB method, a memory controller receives write instructions specifying a logical address, converts the logical address to a physical address on the basis of a conversion table, specifies a write destination memory line on the basis of the physical address, and counts the number of times each memory line is written. If there is a memory line which is written a large number of times, then the memory controller swaps a logical address corresponding to a physical address of the memory line with a logical address corresponding to a physical address of a memory line which is written a small number of times.

Start gap wear leveling (hereinafter referred to as the SG method) is proposed as an example of a method other than the TB method. With the SG method wear leveling is realized by setting one memory line as a gap line (to which data is not written) and shifting the position of the gap line in order. The SG method presupposes the following initial state. Logical addresses are assigned in the order of physical addresses and a memory line corresponding to the last physical address is set as a gap line.

With the SG method a memory controller counts the number of times all memory lines are written. When a count value reaches a certain number, the memory controller shifts the position of a gap line to a physical address one before a current physical address. At this time the memory controller copies data in a shift destination memory line to the gap line and sets the shift destination memory line as the gap line. With the SG method the memory controller seizes the correspondence between a logical address and a physical address on the basis of the number of times the position of the gap line is shifted.

Improved SG methods are also proposed. For example, all memory lines are divided into a plurality of regions and the SG method is applied by regions. Furthermore, a technique for securing the reliability of data written to a nonvolatile memory including plural kinds of memories which differ in guaranteed rewrite count is proposed. With this technique, the number of times a memory whose guaranteed rewrite count is low is written is counted for each partition. When the counted number of times exceeds a determined number, control is exercised so as to write data to a memory whose guaranteed rewrite count is high.

See, for example, the following documents:

Japanese Laid-open Patent Publication No. 2011-44207;

Moinuddin K. Qureshi et al., “Enhancing Lifetime and Security of PCM-Based Main Memory with Start-Gap Wear Leveling”, MICRO 2009;

Lei Jiang et al., “LLS: Cooperative integration of wear-leveling and salvaging for PCM main memory”, 2011 41st IEEE/IFIP International Conference on Dependable Systems and Networks; and

Hongliang Yu and Yuyang Du, “Increasing Endurance and Security of Phase-Change Memory with Multi-way Wear-Leveling”, Computers, IEEE Transactions on Vol. 63.

With the TB method, a conversion table is used. With the improvement of the microfabrication technology or the lamination technology, for example, the integration level of storage elements increases. As a result, the size of a conversion table increases with an increase in memory size. Accordingly, memory size occupied by a conversion table increases and it takes time to convert a logical address to a physical address.

With the SG method, on the other hand, a conversion table is not used and a logical address is converted to a physical address by calculation on the basis of, for example, the number of times a shift is performed. Therefore, even if there is an increase in memory size, the above problem with the TB method does not arise. However, the efficiency of wear leveling (effect of distributing write destinations) by the SG method is low compared with the TB method. As stated above, the improved SG methods are also proposed. However, there is still room for improvement in the efficiency of wear leveling.

### SUMMARY

According to an aspect, there is provided a storage apparatus including: a physical memory including a plurality of first memory lines and a second memory line which is assigned one of consecutive addresses, a part of the plurality of first memory lines being assigned the consecutive addresses and a rest of the plurality of first memory lines being put into an unassigned state in which no address is assigned; a determination unit which determines on the basis of an address whether a write access to the physical memory is a write access to one of the plurality of first memory lines or a write access to the second memory line; a counting unit which finds a plurality of first count values indicative of numbers of times the plurality of first memory lines are written and a second count value indicative of a number of times the second memory line is written; and a control unit which uses, when a total sum of the plurality of first count values and the second count value exceeds a determined threshold, a first memory line in the unassigned state for swapping the address assigned to the second memory line with one of the addresses assigned to the part of the plurality of first memory lines.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 illustrates an example of an information processing system according to a first embodiment;

FIG. 2 illustrates an example and modifications of mounting an arithmetic and logic unit and a storage unit on hardware according to a second embodiment;

FIG. 3 is a block diagram which illustrates the functions and the like of a memory controller and a memory module included in the storage unit according to the second embodiment;

FIG. 4 is a block diagram which illustrates the functions and the like of a memory controller and a memory module included in a storage unit according to a modification of the second embodiment;

FIG. 5 is a view for describing a method for controlling a memory line shift, according to the second embodiment;

FIG. 6 is a view for describing a method for controlling memory line swapping, according to the second embodiment (part 1);

FIG. 7 is a view for describing a method for controlling memory line swapping, according to the second embodiment (part 2);

FIG. 8 is a view for describing the number of preferential lines included in the memory module in the second embodiment;

FIG. 9 is a flow chart which illustrates the flow of a process performed by the memory controller in the second embodiment (part 1);

FIG. 10 is a flow chart which illustrates the flow of a process performed by the memory controller in the second embodiment (part 2); and

FIG. 11 indicates an effect obtained by applying a technique according to the second embodiment.

### DESCRIPTION OF EMBODIMENTS

Embodiments will now be described with reference to the accompanying drawings. Duplicate descriptions of components in this specification and the drawings having substantially the same functions may be omitted by marking them with the same numerals.

### 1. First Embodiment

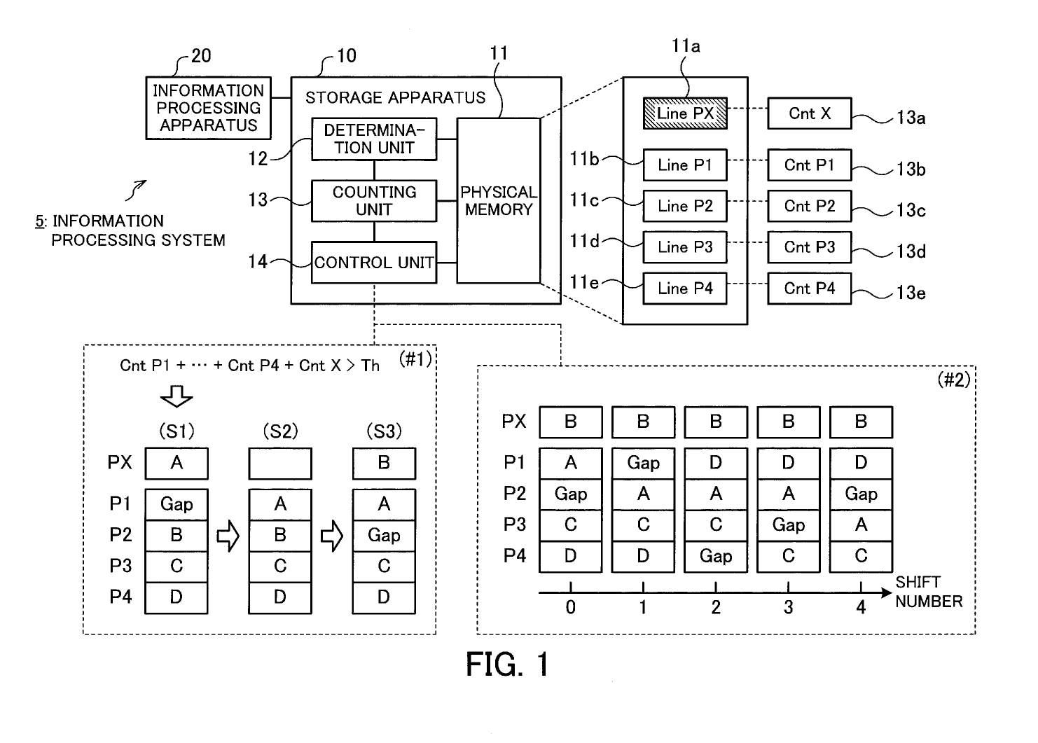

A first embodiment will be described with reference to FIG. 1. FIG. 1 illustrates an example of an information processing system according to a first embodiment.

The first embodiment is related to the technique of counting, at the time of writing data to a physical memory including a plurality of memory lines, the number of times each memory line is written and controlling the correspondence between an address (logical address) and a memory line according to a count value. In addition, the first embodiment provides a method for improving the efficiency of wear leveling by dividing a plurality of memory lines into two groups (preferential line group and ordinary line group) and combining control exercised in the ordinary line group and control exercised over the preferential line group and the ordinary line group. The technique according to the first embodiment will now be described with an information processing system 5 illustrated in FIG. 1 as an example.

As illustrated in FIG. 1, the information processing system 5 includes a storage apparatus 10 and an information processing apparatus 20. The storage apparatus 10 stores data. The information processing apparatus 20 is connected to the storage apparatus 10 and reads out data from or writes data to the storage apparatus 10.

The storage apparatus 10 includes a physical memory 11, a determination unit 12, a counting unit 13, and a control unit 14. The physical memory 11 is a memory module including a nonvolatile memory element such as a NAND flash memory, a ReRAM, a PCM, or an STT-MRAM. The physical memory 11 may also include a volatile memory element such as a dynamic random access memory (DRAM). The determination unit 12, the counting unit 13, and the control unit 14 are components of a memory controller which controls the physical memory 11.

The information processing apparatus 20 is a computer, such as a server, which includes a processor module including a processor, such as a central processing unit (CPU), a digital signal processor (DSP), or a micro processing unit (MPU), and main storage such as a main memory. Data is transferred via a bus, a network, or the like from the information processing apparatus 20 to the storage apparatus 10 or from the storage apparatus 10 to the information processing apparatus 20. The storage apparatus 10 is independent and includes a CPU, a random access memory (RAM), a hard disk drive (HDD), and the like. In the example of FIG. 1, the information processing apparatus 20 makes a request specifying one of addresses A, B, C, and D as a write destination address, to write data to the physical memory 11. The addresses A, B, C, and D are examples of a logical address.

The physical memory 11 includes first memory lines 11b through 11e and a second memory line 11a. The first memory lines 11b through 11e and the second memory line 11a may be equal in rewriting resistance (endurance). However, it is desirable that the endurance of the second memory line 11a be higher than that of the first memory lines 11b through 11e. In addition, nonvolatile memory elements are used for the first memory lines 11b through 11e, whereas volatile or nonvolatile memory elements may be used for the second memory line 11a.

A part of the first memory lines 11b through 11e are assigned the consecutive addresses A, B, C, and D and the rest of the first memory lines 11b through 11e are put into an unassigned state in which none of the addresses A, B, C, and D is assigned. Hereinafter a memory line in the unassigned state may be referred to as a gap line Gap. The second memory line 11a is assigned one of the consecutive addresses A, B, C, and D. In the example of FIG. 1, the first memory lines 11b through 11e are identified by physical addresses P1 through P4 respectively. The second memory line 11a is identified by a physical address PX.

The determination unit 12 determines on the basis of the address A, B, C, or D whether a write access to the physical memory 11 is a write access to one of the first memory lines 11b through 11e or a write access to the second memory line 11a. That is to say, if the information processing apparatus 20 specifies the address B as a write destination address, then the determination unit 12 determines which memory line corresponds to the specified address B.

The counting unit 13 finds first count values CntP1 through CntP4 indicative of the numbers of times the first memory lines 11b through 11e, respectively, are written and a second count value CntX indicative of the number of times the second memory line 11a is written.

In the example of FIG. 1, the counting unit 13 finds the first count value CntP1 by the use of a line counter 13b which counts the number of times the first memory line 11b is written. Similarly, the counting unit 13 finds the first count values CntP2 through CntP4 by the use of line counters 13c through 13e which count the numbers of times the first memory lines 11c through 11e, respectively, are written. In addition, the counting unit 13 finds the second count value CntX by the use of a line counter 13a which counts the number of times the second memory line 11a is written.

The control unit 14 determines whether or not the total sum of the first count values CntP1 through CntP4 and the second count value CntX exceeds a determined threshold Th. If the total sum of the first count values CntP1 through CntP4 and the second count value CntX exceeds the threshold Th, then the control unit 14 uses a first memory line in the unassigned state for swapping an address assigned to the second memory line 11a with one of the addresses assigned to the first memory lines.

In the example of FIG. 1 (#1), when the total sum of the first count values CntP1 through CntP4 and the second count value CntX exceeds the threshold Th, the address “A” is assigned to the second memory line 11a corresponding to the physical address PX. This is indicated by S1. In addition, the first memory line 11b corresponding to the physical address P1 is set as a gap line Gap and is in the unassigned state. The addresses “B”, “C”, and “D” are assigned to the first memory lines 11c, 11d and 11e corresponding to the physical addresses P2, P3, and P4 respectively.

In this state, the control unit 14 assigns to the first memory line 11b (P1) the address “A” assigned to the second memory line 11a (S2). The control unit 14 then assigns to the second memory line 11a the address “B” assigned to the first memory line 11c (P2) next to the first memory line 11b (P1). The control unit 14 then puts the first memory line 11c (P2) into the unassigned state, thereby setting the first memory line 11c (P2) as a gap line Gap (S3).

As indicated in FIG. 1 (#2), on the other hand, if the total sum of the first count values CntP1 through CntP4 and the second count value CntX does not exceed the threshold Th, then the control unit 14 shifts a gap line Gap in the range of the first memory lines 11b to 11e, depending on the first count values CntP1 through CntP4. For example, a case where the total sum of the first count values CntP1 through CntP4 and the second count value CntX exceeds a shift threshold or a case where a specific first memory line is intensively written (case where a high peak appears in the distribution of the first count values) may be considered as a condition under which this shift occurs (shift condition).

If the shift condition is satisfied, then the control unit 14 assigns to the first memory line 11c set as a gap line Gap the address “A” assigned to the first memory line 11b located before the first memory line 11c. The control unit 14 then sets the first memory line 11b as a gap line Gap. In addition, the control unit 14 holds the number of times it performs a shift (shift number).

An address assignment situation is obtained from the address “A” assigned to the first memory line 11b at the time of a shift number being 0, the physical address “P2” of the first memory line 11c set as a gap line Gap at the time of a shift number being 0, and a shift number.

In the example of FIG. 1 (#2), for example, if a shift number is “2,” the gap line Gap shifts by two memory lines (that is to say, P2→P1→P4) and therefore the first memory line 11e is set as a gap line Gap. Furthermore, the addresses “D,” “A,” and “C” assigned to the first memory lines 11b, 11c, and 11d, respectively, are calculated. Therefore, there is no need to use a conversion table in which the relationship between an address and each of the first memory lines 11b through 11e is described. This saves storage capacity compared with the TB method.

Even if the above shift process is performed, there is a possibility that a specific memory line is intensively written. However, assignment of addresses to memory lines is controlled, independently of the above shift process, by the process indicated in FIG. 1 (#1), so efficiency in wear leveling is high compared with the SG method. That is to say, with the SG method a gap line Gap is shifted on the basis of one shift rule. However, assignment control indicated in FIG. 1 (#1) is exercised on the basis of a rule which is independent of the shift rule. As a result, the effect of distributing write destinations is increased and an improvement in the efficiency of wear leveling is expected.

In addition, using high endurance memory elements for the second memory line 11a increases resistance of the second memory line 11a against intensive writes. If high endurance memory elements are used to allow the second memory line 11a to be intensively written, the loads on the first memory lines 11b through 11e become lighter. Therefore, the endurance and reliability of the physical memory 11 are improved.

For example, if the control unit 14 takes an address assigned to a first memory line, of the first memory lines 11b through 11e, corresponding to the greatest first count value as an object of swapping, then the effect of improving the endurance and reliability of the physical memory 11 is heightened.

In the example of FIG. 1, if an address assigned to the second memory line 11a is assigned to a first memory line 11b, 11c, 11d, or 11e set as a gap line Gap, then the addresses A through D are assigned so that the addresses A through D will appear in succession in accordance with the order in which the first memory lines 11b through 11e are arranged. In this case, after the swapping process indicated by S1 through S3 in FIG. 1 (#1) is performed, a reassignment operation for arranging the addresses in the order of A, B, C, and D may be performed, depending on the position of a gap line Gap.

Accordingly, it is desirable that, before assigning an address assigned to the second memory line 11a to the first memory line 11b, 11c, 11d, or 11e set as a gap line Gap, the control unit 14 determine whether or not the order of the addresses A, B, C, and D is maintained, and then perform a swapping process if it is determined that the order of the addresses A, B, C, and D is maintained. In the example of FIG. 1 (#1), the above swapping process is performed at the timing at which the address “B” that follows the address “A” is located at the first memory line 11c next to the gap line Gap. In this case, as indicated in FIG. 1 (#1), an address swapping process is completed by a minimum assignment operation with the order of the addresses A, B, C, and D maintained.

As has been described, the second memory line 11a is considered as a preferential line, the first memory lines 11b through 11e are considered as ordinary lines, and line control in the range of the ordinary lines and line control over the preferential line and the ordinary lines are combined. By doing so, an improvement in the efficiency of wear leveling is expected. In addition, with the preferential line having higher endurance than the ordinary lines, the physical memory 11 achieves higher endurance and reliability. Furthermore, by properly controlling timing at which line control is exercised over the preferential line and the ordinary lines according to the position of a gap line Gap, a processing load is reduced.

The foregoing is an explanation of the first embodiment.

### 2. Second Embodiment

A second embodiment will now be described.

The second embodiment is related to the technique of counting, at the time of writing data to a physical memory including a plurality of memory lines, the number of times each memory line is written and controlling the correspondence between a logical address and a memory line according to a count value. In addition, the second embodiment provides a method for improving the efficiency of wear leveling by dividing a plurality of memory lines into a preferential line group and an ordinary line group and combining control exercised in the ordinary line group and control exercised over the preferential line group and the ordinary line group.

(2-1. Mounting on Hardware)

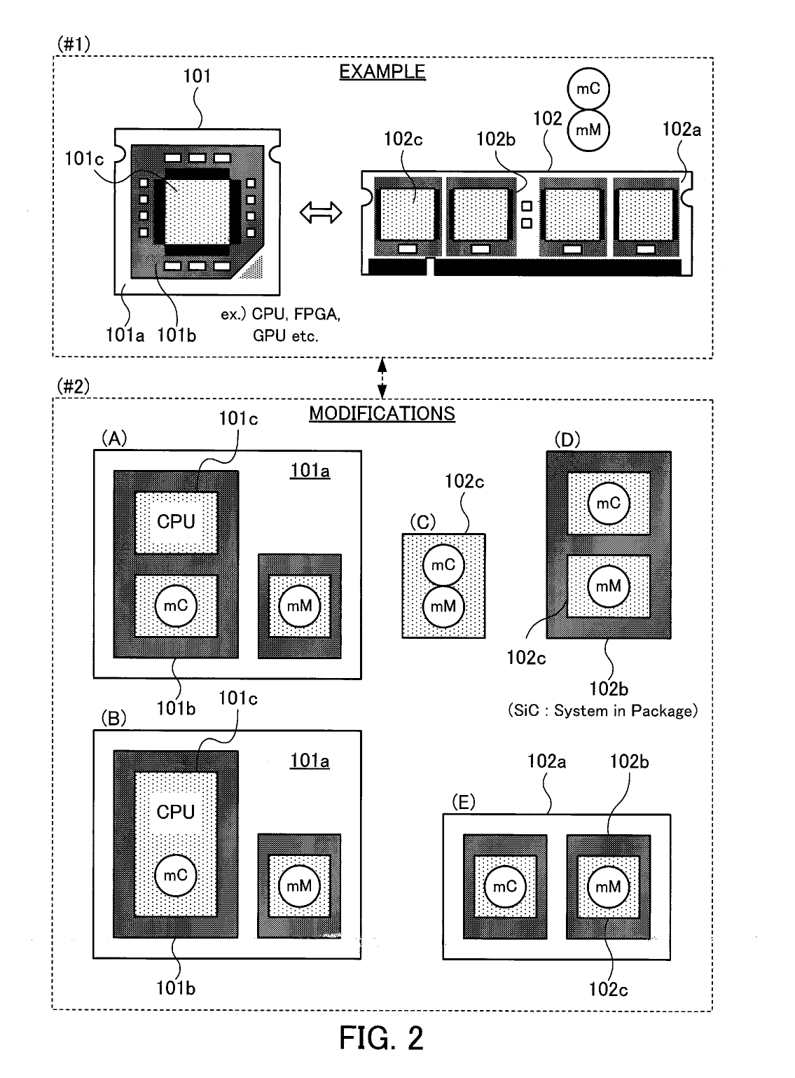

The technique according to the second embodiment is realized by a memory module mM including a plurality of memory lines and a memory controller mC which exercises control over each memory line included in the memory module mM. An example of mounting the memory module mM and the memory controller mC on hardware will now be described. FIG. 2 illustrates an example and modifications of mounting an arithmetic and logic unit and a storage unit on hardware according to the second embodiment.

FIG. 2 (#1) illustrates an arithmetic and logic unit 101 and a storage unit 102 included in a computer as examples of hardware to which the technique according to the second embodiment is applicable. The arithmetic and logic unit 101 is a CPU, an FPGA, a graphics processing unit (GPU), or the like. The storage unit 102 communicates with the arithmetic and logic unit 101 via a bus, a network, or the like.

For example, the arithmetic and logic unit 101 is realized by mounting a package 101b including an arithmetic chip 101c on a printed circuit board (PCB) 101a. The package 101b or the arithmetic chip 101c may include a memory chip such as a cache memory. A memory chip is an example of a physical memory. A package other than the package 101b including the arithmetic chip 101c may be mounted on the PCB 101a.

For example, the storage unit 102 is realized by mounting a package 102b including a memory chip 102c on a PCB 102a. The memory chip 102c is an example of a physical memory. The memory chip 102c or the package 102b may include a control chip (operational circuit) which controls the operation of the memory chip 102c. A package other than the package 102b including the memory chip 102c may be mounted on the PCB 102a.

In the example of FIG. 2 (#1), the memory module mM and the memory controller mC are mounted in the storage unit 102. For example, the memory chip 102c functions as the memory module mM and the control chip included in the package 102b functions as the memory controller mC. For example, various modifications illustrated in FIG. 2 (#2) are possible in addition to the example of FIG. 2 (#1).

With modification (A), the package 101b of the arithmetic and logic unit 101 includes a control chip which functions as the memory controller mC, and a package including a memory chip which functions as the memory module mM is mounted on the PCB 101a. With modification (B) the arithmetic chip 101c functions as the memory controller mC.

With modification (C) the memory chip 102c of the storage unit 102 functions as the memory module mM and the memory controller mC. With modification (D), the memory chip 102c functions as the memory module mM and the package 102b includes a control chip other than the memory chip 102c which functions as the memory controller mC. Modification (D) is referred to as a system in package (SiP). With modification (E), the memory chip 102c functions as the memory module mM and the package 102b including a control chip which functions as the memory controller mC is mounted on the PCB 102a.

The scope of the technique according to the second embodiment is not limited to the above example or modifications. By adopting the above mounting methods, however, the technique is materialized by hardware resources.

(2-2. Functional Blocks)

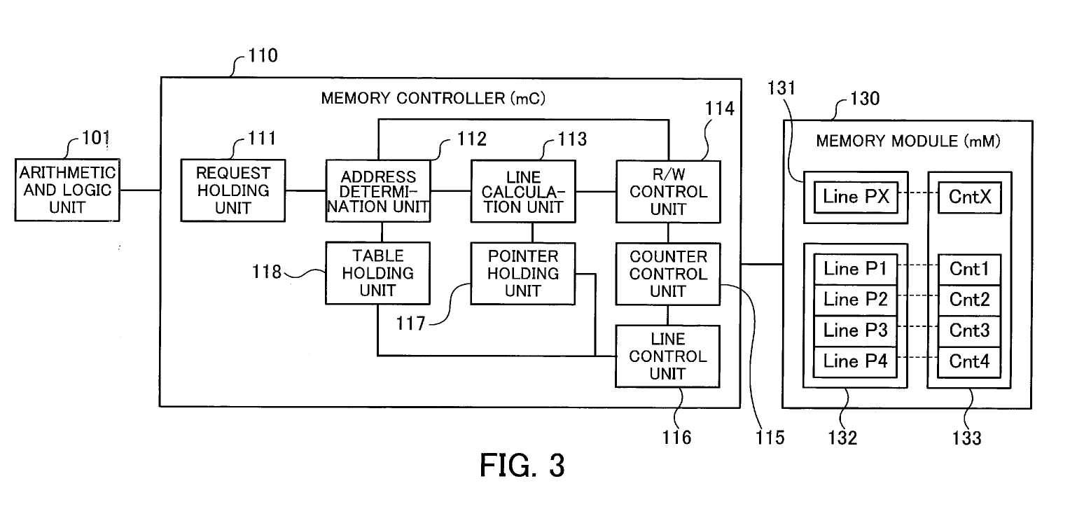

The functions of the memory controller mC and the memory module mM will now be described with reference to FIG. 3. FIG. 3 is a block diagram which illustrates the functions and the like of a memory controller and a memory module included in the storage unit according to the second embodiment. A memory controller 110 illustrated in FIG. 3 is an example of the memory controller mC. In addition, a memory module 130 illustrated in FIG. 3 is an example of the memory module mM.

The memory controller 110 includes a request holding unit 111, an address determination unit 112, a line calculation unit 113, an R/W control unit 114, a counter control unit 115, a line control unit 116, a pointer holding unit 117, and a table holding unit 118.

On the other hand, the memory module 130 includes a high endurance (HE) memory 131, a low endurance (LE) memory 132, and a counter 133. The rewriting resistance (endurance) of the HE memory 131 is higher than that of the LE memory 132. For example, a DRAM, a single level cell (SLC), or a ReRAM may be used as the HE memory 131. However, even if the HE memory 131 and the LE memory 132 are equal in endurance, the technique according to the second embodiment is applicable.

In the example of FIG. 3, a memory line having a physical address PX is set in the HE memory 131. Hereinafter the memory line in the HE memory 131 may be referred to as a preferential line. A plurality of memory lines having physical addresses P1 through P4, respectively, are set in the LE memory 132. Hereinafter a memory line in the LE memory 132 may be referred to as an ordinary line. Furthermore, a memory line having a physical address Pk (k=1, 2, 3, 4, or X) may be represented as a memory line Pk.

The counter 133 counts the number of times each memory line set in the HE memory 131 and the LE memory 132 is written. Hereinafter the numbers of times the memory lines PX, P1, P2, P3, and P4 are written are represented as CntX, Cnt1, Cnt2, Cnt3, and Cnt4 respectively. That is to say, CntX, Cnt1, Cnt2, Cnt3, and Cnt4 are count values obtained by the counter 133.

If a read/write request is received from the arithmetic and logic unit 101 during a process for reading from or writing to the memory module 130, the request holding unit 111 temporarily holds the read/write request. The address determination unit 112 determines whether or not a read/write destination logical address specified in the read/write request corresponds to the preferential line. At this time the address determination unit 112 refers to a conversion table held by the table holding unit 118. The conversion table associates the preferential line with a logical address.

The address determination unit 112 informs the R/W control unit 114 of a determination result. Furthermore, if the read/write destination logical address does not correspond to the preferential line, then the address determination unit 112 informs the line calculation unit 113 of the read/write destination logical address. The line calculation unit 113 calculates an ordinary line corresponding to the read/write destination logical address of which the address determination unit 112 informs the line calculation unit 113. The line calculation unit 113 informs the R/W control unit 114 of a calculation result.

The R/W control unit 114 specifies a read/write destination memory line on the basis of the notice received from the address determination unit 112 or the line calculation unit 113, and performs a process for reading from or writing to the specified memory line. In the case of a read process, the R/W control unit 114 transmits to the arithmetic and logic unit 101 data which it reads out from the memory line. In the case of a write process, on the other hand, the R/W control unit 114 informs the counter control unit 115 of the memory line to which it writes data.

The counter control unit 115 controls the counter 133 to increment a count value for the memory line of which the R/W control unit 114 informs the counter control unit 115. The line control unit 116 controls assignment of a logical address to each memory line. Furthermore, the line control unit 116 monitors a count value for each memory line. If the total sum of count values for the ordinary lines exceeds a threshold set in advance, then the line control unit 116 shifts a gap line set on an ordinary line. At this time the line control unit 116 exercises shift control or swapping control described later.

After the line control unit 116 exercises the shift control or the swapping control, the line control unit 116 specifies a pointer (Start or Gap) indicative of the position of a specific memory line which the line calculation unit 113 refers to at the time of calculating a physical address from a logical address, and informs the pointer holding unit 117 of the pointer. Furthermore, after the line control unit 116 exercises the swapping control, the line control unit 116 updates the conversion table held by the table holding unit 118.

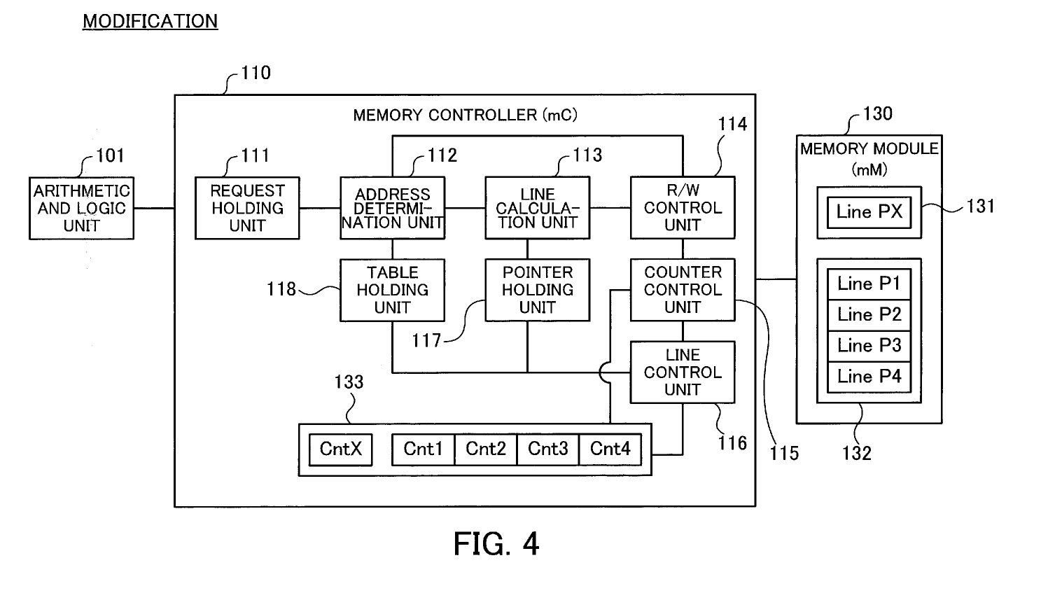

The functions of the memory controller mC and the memory module mM have been described. As illustrated in FIG. 4, the counter 133 may be included in the memory controller 110. FIG. 4 is a block diagram which illustrates the functions and the like of a memory controller and a memory module included in a storage unit according to a modification of the second embodiment.

(2-3. Line Control Method)

A processing method regarding memory line control will now be described.

(2-3-1. Ordinary Line Update Operation)

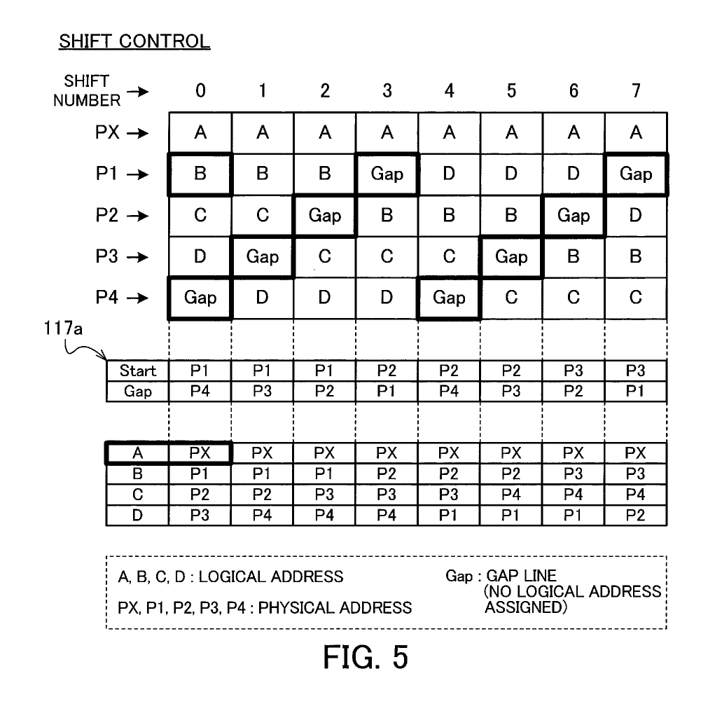

First shift control which is an ordinary line update operation will be described with reference to FIG. 5. As stated above, this shift control is exercised mainly by the line control unit 116. FIG. 5 is a view for describing a method for controlling a memory line shift, according to the second embodiment.

In the example of FIG. 5, in an initial state (shift number=0), logical addresses A, B, C, and D are assigned to memory lines PX, P1, P2, and P3 respectively and a memory line P4 is set as a memory line (gap line) which is not assigned a logical address. It is assumed that the order in which the logical addresses are arranged is set to A→B→C→D (alphabetical order) and that the order in which physical addresses of ordinary lines are arranged is set to P1→P2→P3→P4 (numerical order).

In the initial state the pointer holding unit 117 holds a pointer Start indicative of the position (physical address) of the logical address B assigned to the memory line P1 at the head of the ordinary lines. In addition, the pointer holding unit 117 holds a pointer Gap indicative of the position (physical address) of a memory line set as a gap line. In FIG. 5, the position of a gap line is indicated by Gap. As illustrated in FIG. 5, a combination 117a of these pointers changes each time the line control unit 116 exercises shift control.

The shift control is exercised in the range of the ordinary lines (memory lines P1 through P4). If a condition (shift condition) under which shift control is exercised is satisfied, then the line control unit 116 shifts a gap line to a memory line one before the current memory line. For example, the line control unit 116 shifts a gap line set on the memory line P4 to the memory line P3. At this time the line control unit 116 copies data in the shift destination memory line to the shift source memory line and sets the shift destination memory line as a gap line.

If a shift number is three in the example of FIG. 5, that is to say, if the line control unit 116 exercises shift control in a state in which the memory line P1 is set as a gap line, then the line control unit 116 shifts the gap line to the memory line P4 positioned last. As illustrated in FIG. 5, if shift control is repeated, the physical addresses P1, P2, P3, and P4 corresponding to the logical addresses B, C, and D change each time the line control unit 116 exercises shift control. However, assignment to the preferential line does not change even if the line control unit 116 exercises shift control.

(2-3-2. Preferential Line Update Operation)

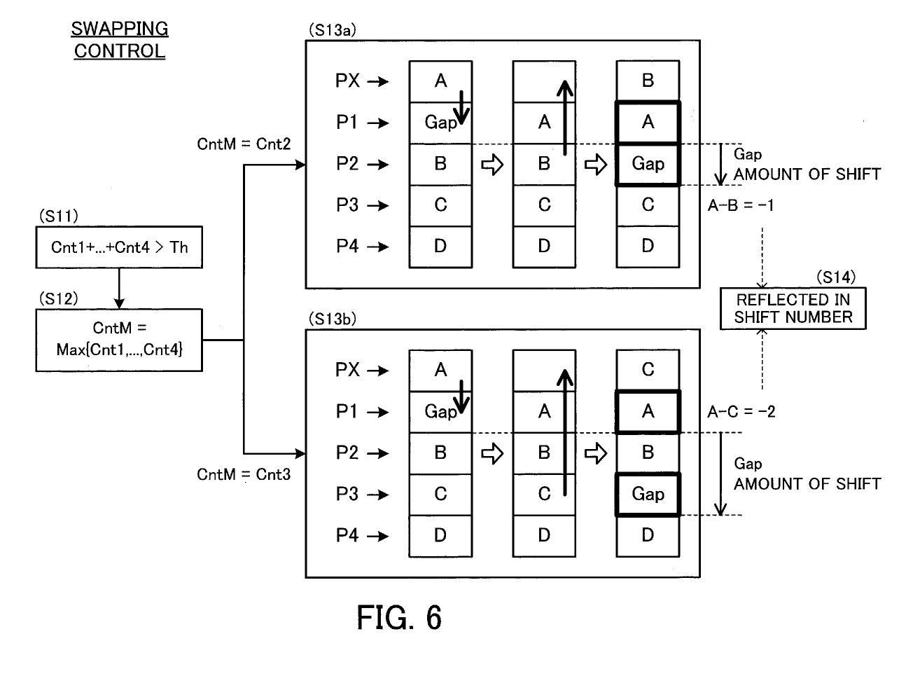

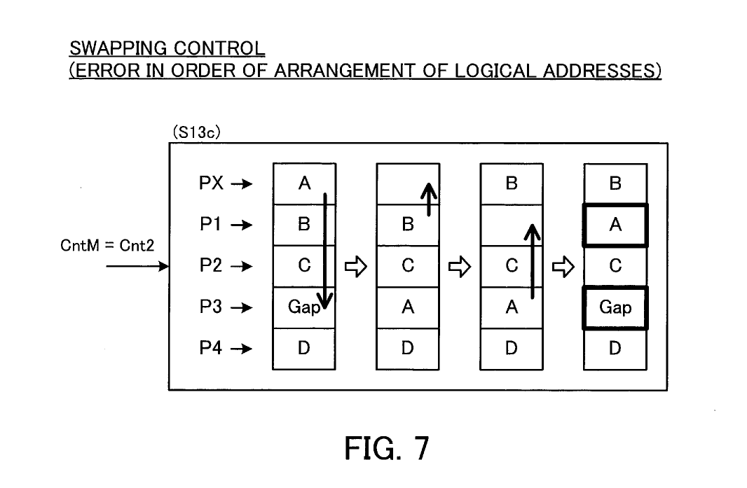

Next, swapping control which is a preferential line update operation will be described with reference to FIGS. 6 and 7. As stated above, this swapping control is exercised mainly by the line control unit 116. FIG. 6 is a view for describing a method for controlling memory line swapping, according to the second embodiment (part 1). FIG. 7 is a view for describing a method for controlling memory line swapping, according to the second embodiment (part 2).

FIG. 6 exemplifies swapping control that is exercised when a condition (swapping condition) under which swapping control is exercised is satisfied in a state in which a shift number is three in the example of FIG. 5. The swapping condition is that the total sum of count values (Cnt1+Cnt2+Cnt3+Cnt4) for the ordinary lines exceeds a threshold Th set in advance (S11). If the swapping condition is satisfied, then the line control unit 116 specifies the greatest count value CntM of the count values for the ordinary lines (S12).

The line control unit 116 then assigns to the preferential line a logical address assigned to a memory line corresponding to CntM, and assigns to a gap line a logical address assigned to the preferential line. In addition, the line control unit 116 sets the memory line corresponding to CntM as a gap line. For example, if CntM is Cnt2, then swapping control is indicated by S13a. If CntM is Cnt3, then swapping control is indicated by S13b.

After the line control unit 116 exercises swapping control, the line control unit 116 updates pointers Start and Gap and adjusts a shift number by the amount of a shift in the gap line (S14). In the case of S13a, for example, the logical address assigned to the preferential line is changed from A to B as a result of the swapping control. Accordingly, the line control unit 116 considers the difference between the logical addresses as the amount of a shift. (In this case, there is a shift from the first logical address to the second logical address, so −1 (=1−2) is obtained as the amount of the shift.) In the example of FIG. 6, swapping control is exercised in a state in which a shift number is three. Accordingly, 1−3=−2 and the shift number is adjusted to two.

Furthermore, the line control unit 116 updates the conversion table. That is to say, the line control unit 116 updates the conversion table so as to associate the physical address PX of the preferential line with a logical address (B in the case of S13a and C in the case of S13b) newly assigned to the preferential line. Pointers after the update by the line control unit 116 are held by the pointer holding unit 117 and a conversion table after the update is held by the table holding unit 118.

A method for performing a preferential line update operation in the case of the total sum of count values for the ordinary lines exceeding the threshold Th has been described. However, a preferential line update operation may be performed in the case of the total sum of count values for the ordinary lines and a count value for the preferential line exceeding the threshold Th.

(Swapping Control Timing)

In the example of FIG. 6, a logical address of the preferential line is assigned to a gap line and a logical address of a memory line corresponding to CntM is assigned to the preferential line. By doing so, the order in which the logical addresses are arranged in the range of the ordinary lines is maintained. As illustrated in FIG. 7, however, there is a case where the arrangement of the logical addresses is out of order (where there occurs an error in the order of the arrangement of the logical addresses), depending on the timing at which swapping control is exercised. In this case, as illustrated in FIG. 7 (S13c), the line control unit 116 repeats logical address swapping to realize the correct order of the arrangement of the logical addresses.

However, when logical address swapping is performed, data in a memory line which is an object of swapping is copied. Accordingly, a reduction in the number of times logical address swapping is performed leads to a reduction in processing load. That is to say, if the swapping condition is satisfied and the correct order of the arrangement of the logical addresses is realized in a state in which a logical address of the preferential line is assigned to a gap line, the line control unit 116 may exercise swapping control.

As illustrated in FIG. 6 (S13a), for example, the time when the logical address (B) assigned to the memory line (P2) next to the gap line (P1) matches the logical address (B) next to the logical address (A) assigned to the preferential line is suitable timing for swapping control. By making such a timing adjustment, an error in the order of the arrangement of the logical addresses illustrated in FIG. 7 does not occur when swapping control is exercised. As a result, a processing load with which swapping control is attended is reduced. This contributes to high-speed processing.

(Number of Preferential Lines)

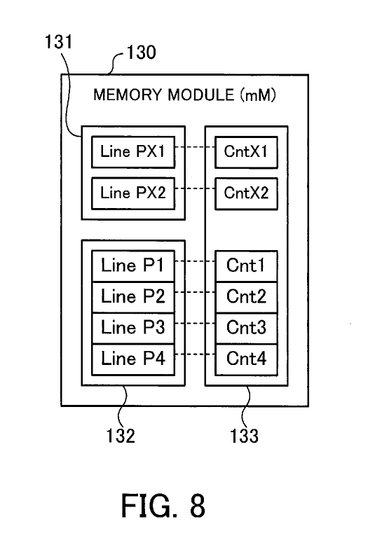

For convenience of explanation it has been assumed that the number of preferential lines is one. As illustrated in FIG. 8, however, a plurality of preferential lines may be included. FIG. 8 is a view for describing the number of preferential lines included in the memory module in the second embodiment. In this case, the line control unit 116 selects a preferential line suitable for the swapping of a memory line corresponding to CntM and exercises the above swapping control with the selected preferential line as an object. A process flow described later indicates the flow of a process in which a case where there are a plurality of preferential lines is taken into consideration.

(2-4. Process Flow)

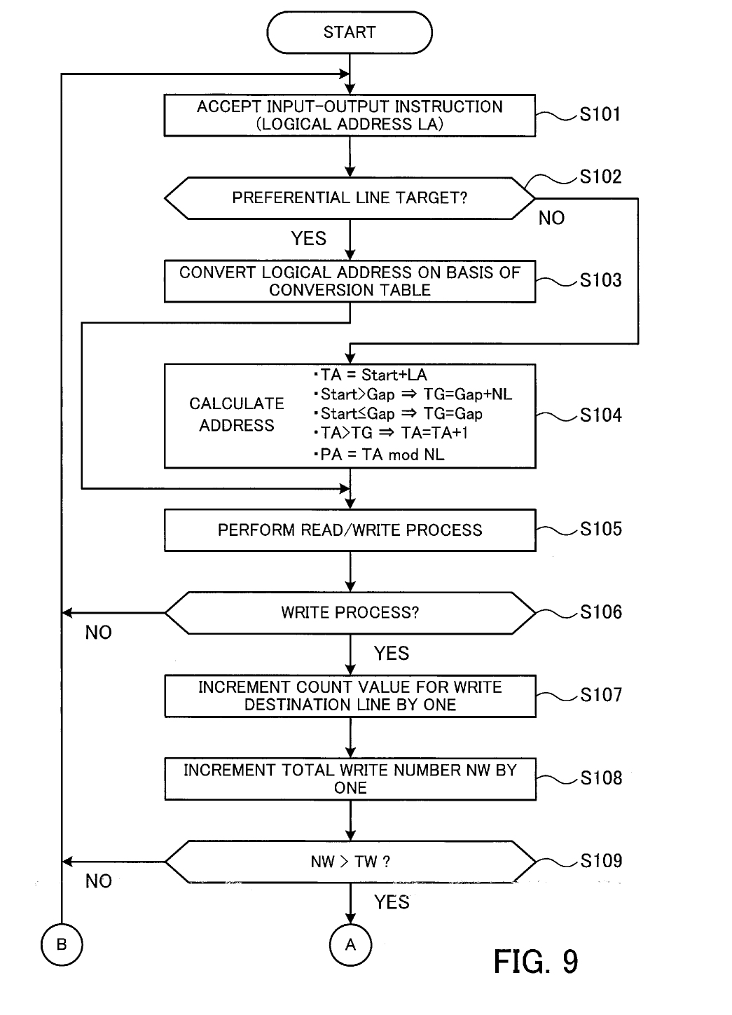

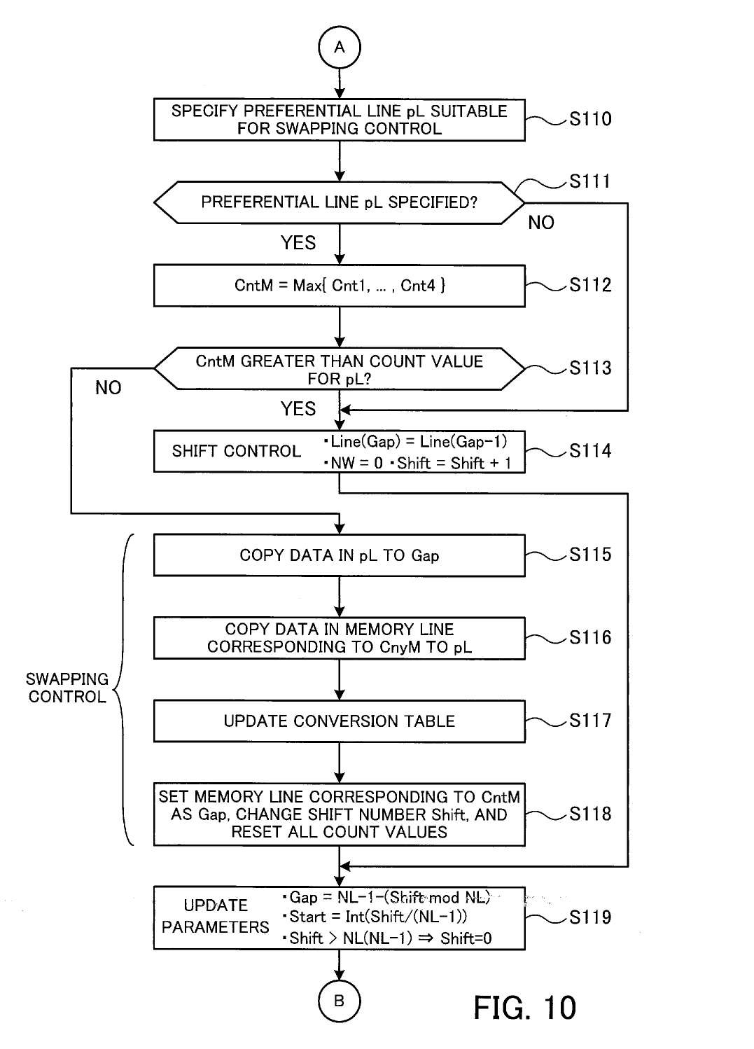

The flow of a process performed by the memory controller 110 will be described with reference to FIGS. 9 and 10. FIG. 9 is a flow chart which illustrates the flow of a process performed by the memory controller in the second embodiment (part 1). FIG. 10 is a flow chart which illustrates the flow of a process performed by the memory controller in the second embodiment (part 2). The process illustrated in FIGS. 9 and 10 ends if the determined end condition (that power is turned off, for example) is satisfied.

(S101) The request holding unit 111 accepts an input-output instruction which is issued by the arithmetic and logic unit 101 to make a request to read from or write to the memory module 130. At this time the request holding unit 111 acquires a read/write destination logical address LA. In addition, if the memory module 130 is performing another read/write process, then the request holding unit 111 holds the input-output instruction which it accepts.

(S102) The address determination unit 112 determines whether or not a preferential line is a target for the input-output instruction accepted by the request holding unit 111. For example, the address determination unit 112 refers to a conversion table held by the table holding unit 118, and determines whether or not LA is registered as a logical address corresponding to a physical address PX of the preferential line. If the preferential line is a target for the input-output instruction accepted by the request holding unit 111, then S103 is performed. On the other hand, if the preferential line is not a target for the input-output instruction accepted by the request holding unit 111, then S104 is performed.

(S103) The address determination unit 112 converts the logical address LA to a physical address PA on the basis of the conversion table held by the table holding unit 118.

(S104) The line calculation unit 113 performs a calculation to specify a physical address PA of an ordinary line to which the logical address LA is assigned. At this time the line calculation unit 113 uses parameters TA and TG (initial value: TA=TG=0).

Hereinafter the total number of ordinary lines, a pointer of a gap line, and a pointer indicative of the position of a logical address assigned to a memory line at the head of the ordinary lines in an initial state (state in which a shift number is 0) are represented as NL, Gap, and Start respectively. For example, if a shift number is four in the example of FIG. 5, Gap is 3 (if the position of the memory line P1 is represented as a pointer 0) and Start is 1. In this example, NL is 4.

The line calculation unit 113 calculates “TA=Start+LA”. Next, the line calculation unit 113 determines whether or not “Start>Gap”. If Start>Gap, then the line calculation unit 113 calculates “TG=Gap+NL”. On the other hand, if Start≦Gap, then the line calculation unit 113 considers that “TG=Gap”. Next, the line calculation unit 113 determines whether or not “TA>TG”. If TA>TG, then the line calculation unit 113 increments TA by one. Next, the line calculation unit 113 calculates

PA=TA mod NL

where mod represents a remainder operation.

(S105) The R/W control unit 114 performs a process for reading data from or writing data to the physical address PA obtained in S103 or S104.

(S106) The counter control unit 115 determines whether or not the process performed in S105 is a write process. If the process performed in S105 is a write process, then S107 is performed. On the other hand, if the process performed in S105 is a read process, then S101 is performed.

(S107) The counter control unit 115 controls the counter 133 and increments a count value corresponding to a memory line (write destination line) having the physical address PA by one.

(S108) The counter control unit 115 increments the total sum of count values for the ordinary lines (total write number NW) by one.

(S109) The line control unit 116 determines whether or not NW>TW. TW is a threshold set in advance. TW is set on the basis of the endurance of the ordinary lines, experimental results, or the like. If NW>TW, then S110 (FIG. 10) is performed. On the other hand, if NW≦TW, then S101 is performed.

(S110) The line control unit 116 specifies a preferential line pL suitable for swapping control. That is to say, the line control unit 116 specifies a preferential line pL by which an error in the order of the arrangement of logical addresses like that illustrated in FIG. 7 does not occur in the case of exercising swapping control.

For example, if a logical address next to a logical address assigned to a target preferential line matches a logical address assigned to an ordinary line next to a gap line, then the line control unit 116 considers the target preferential line as the preferential line pL (see FIG. 6). Even if there are a plurality of preferential lines as illustrated in FIG. 8, the number of preferential lines pL specified in S110 is one at the most.

(S111) The line control unit 116 determines whether or not the preferential line pL is specified in S110. If the preferential line pL is specified in S110, then S112 is performed. If a preferential line pL is not specified in S110, then S114 is performed.

(S112) The line control unit 116 extracts the greatest count value CntM from count values Cnt1 through Cnt4 corresponding to the ordinary lines.

(S113) The line control unit 116 determines whether or not CntM is greater than a count value indicative of the number of times the preferential line pL is written. If CntM is greater than the count value indicative of the number of times the preferential line pL is written, then S114 is performed. On the other hand, if CntM is smaller than the count value indicative of the number of times the preferential line pL is written, then S115 is performed. That is to say, if the preferential line pL which is an object of swapping is written more intensively, then swapping control is not exercised over the preferential line pL.

(S114) The line control unit 116 exercises shift control. That is to say, the line control unit 116 copies data in a memory line which becomes a gap line after a shift to a memory line which is a gap line before the shift, and shifts the gap line to the shift destination memory line (Line(Gap)=Line(Gap−1)). In addition, the line control unit 116 resets the total sum NW of the numbers of times the ordinary lines are written to zero and increments a parameter Shift indicative of a shift number by one. When S114 is completed, S119 is performed.

(S115) The line control unit 116 copies data in the preferential line pL to a gap line. That is to say, in fact, the line control unit 116 assigns a logical address assigned to the preferential line pL to a memory line (ordinary line) corresponding to the copy destination gap line. However, assignment of a logical address to an ordinary line is performed by calculation by the line calculation unit 113. Therefore, for example, addresses are not registered in a table or the like.

(S116) The line control unit 116 copies data in a memory line corresponding to CntM to the preferential line pL. That is to say, in fact, the line control unit 116 assigns a logical address assigned to the memory line corresponding to CntM to the preferential line pL.

(S117) The line control unit 116 updates the conversion table. Unlike the case of S115, assignment of a logical address to the preferential line pL is not performed by calculation by the line calculation unit 113. Therefore, the line control unit 116 makes the conversion table reflect a change in assignment caused by swapping control.

(S118) The line control unit 116 sets the memory line corresponding to CntM as a gap line, changes the shift number Shift, and resets all the count values in the counter 133 to zero. As illustrated in FIG. 6 (S14), the shift number Shift is changed on the basis of the difference between the order of a logical address assigned to the preferential line pL before the swapping control and the order of a logical address assigned to the preferential line pL after the swapping control. That is to say, the line control unit 116 sets a new shift number Shift by adding the above difference in the order to the shift number Shift before the swapping control.

(S119) The line control unit 116 updates parameters such as the pointers Gap and Start. For example, the line control unit 116 calculates “Gap=NL−1−(Shift mod NL)” to update the pointer Gap. In addition, the line control unit 116 calculates “Start=Int(Shift/(NL−1))” to update the pointer Start. Furthermore, if Shift>NL(NL−1), then the line control unit 116 resets Shift to zero. When S119 is completed, S101 (FIG. 9) is performed.

The flow of the process performed by the memory controller 110 has been described.

As has been described in the foregoing, by exercising shift control in the range of ordinary lines, a write load is distributed. Furthermore, by exercising swapping control of a preferential line, write loads are equalized even in a situation where a specific ordinary line is still written intensively after shift control. That is to say, by applying the technique according to the second embodiment, efficiency in wear leveling is improved.

With the above shift control a gap line is shifted on the basis of a certain rule, so address conversion is realized without using a conversion table. With the swapping control, on the other hand, a conversion table is used for a preferential line. However, required storage capacity is small compared with the case where a conversion table regarding all memory lines including ordinary lines is held. That is to say, according to the second embodiment, an improvement in the efficiency of wear leveling is expected compared with the SG method. Furthermore, unlike the TB method, there is no need to hold a large-scale conversion table. This saves storage capacity.

(Effects)

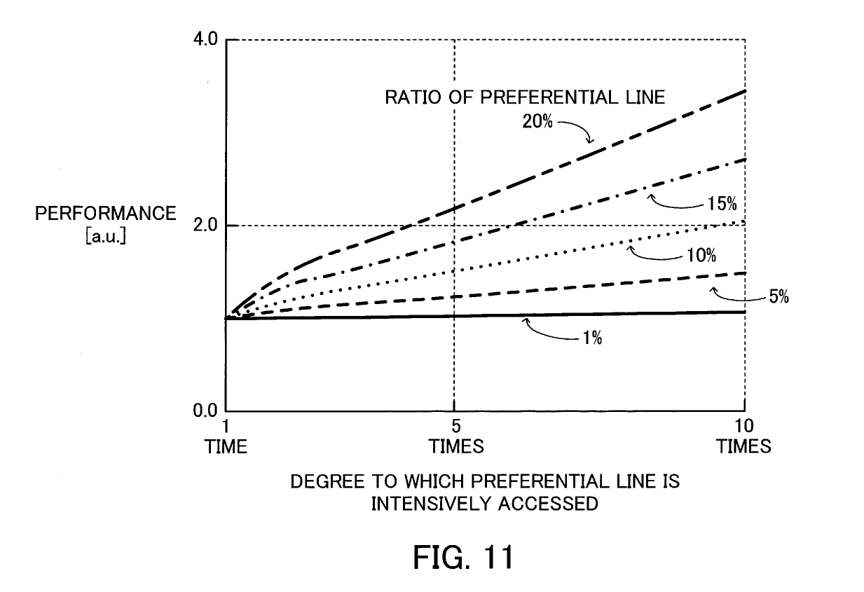

A supplementary explanation of the above effects will be given with reference to FIG. 11. FIG. 11 indicates an effect obtained by applying the technique according to the second embodiment. In FIG. 11, a horizontal axis indicates the degree to which a preferential line is intensively accessed and a vertical axis indicates wear leveling performance (arbitrary unit).

If the total number of lines is N, the number of lines included in the HE memory 131 is X, the degree (times) to which the HE memory 131 is intensively accessed in comparison with the LB memory 132 is a (horizontal axis), and a shift number is S, then the number of times write is performed is roughly evaluated by the following expressions (1) through (3).

$$M = ( N - X ) \{ \frac{S ( N - X )}{N} + 1 \} \qquad ( 1 )$$

where M is the number of times the LE memory 132 is written.

$$R = ( N - X + 1 ) \{ \frac{aS ( N - X )}{N} \} \qquad ( 2 )$$

where R is the number of times the HE memory 131 is written.

$$T = {( N - X )}^{2} \{ \frac{S ( N - X )}{N} + 1 + \frac{aSX}{N} \} \qquad ( 3 )$$

where T is the total number of times write is performed.

It is assumed that if X is zero, M which is the number of times the LE memory 132 is written and T which is the total number of times write is performed are M₀ and T₀ respectively (see the following expressions (4) and (5) respectively).

M₀=N(S+1) (4)

T₀=N²(S+1) (5)

Then an evaluation value G indicative of the degree to which performance is improved is given by

$$G = \frac{{T}_{0}}{T} \frac{M}{{M}_{0}} \qquad ( 6 )$$

FIG. 11 indicates results obtained by evaluating performance with the degree to which a preferential line is intensively accessed by the evaluation value G for each ratio of the preferential line to all memory lines. As can be seen from FIG. 11, the ratio of the preferential line to all memory lines and the degree to which the preferential line is intensively accessed contribute synergistically to an improvement in performance.

A brief mention will be made of the size of a conversion table. It is assumed that the size of the whole of the memory module 130 is N and that the size of each memory line is LS. Then the number NL of memory lines is N/LS. With the TB method the size T of a conversion table is given by

T=2×NL×log₂(NL)

With the second embodiment, on the other hand, the size T of a conversion table is given by

T=M×log₂(NL)

where M is the number of lines included in the HE memory 131.

That is to say, with the second embodiment the size of a conversion table is reduced to M/(2×NL).

The second embodiment has been described.

According to the present disclosure, efficiency in wear leveling is improved further.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A storage apparatus comprising:
a physical memory including a plurality of first memory lines and a second memory line which is assigned one of consecutive addresses, a part of the plurality of first memory lines being assigned the consecutive addresses and a rest of the plurality of first memory lines being put into an unassigned state in which no address is assigned;
a determination unit which determines on the basis of an address whether a write access to the physical memory is a write access to one of the plurality of first memory lines or a write access to the second memory line;
a counting unit which finds a plurality of first count values indicative of numbers of times the plurality of first memory lines are written and a second count value indicative of a number of times the second memory line is written; and
a control unit which uses, when a total sum of the plurality of first count values and the second count value exceeds a determined threshold, a first memory line in the unassigned state for swapping the address assigned to the second memory line with one of the addresses assigned to the part of the plurality of first memory lines.

2. The storage apparatus according to claim 1, wherein, in the swapping, the control unit assigns the address assigned to the second memory line to the first memory line in the unassigned state, assigns to the second memory line an address assigned to a first memory line next to the first memory line having assigned thereto the address previously assigned to the second memory line, and puts the next first memory line into the unassigned state.

3. The storage apparatus according to claim 2, wherein:
assuming that the control unit assigns the address assigned to the second memory line to the first memory line in the unassigned state, the addresses appear consecutively in accordance with an order in which the plurality of first memory lines are arranged; and
the control unit determines, at the time of assigning the address assigned to the second memory line to the first memory line in the unassigned state, whether or not consecutiveness of the addresses is maintained, and performs the swapping at the time of the consecutiveness being maintained.

4. The storage apparatus according to claim 1, wherein the control unit takes an address assigned to a first memory line whose first count value is greatest among the plurality of first memory lines, as an object of the swapping.

5. The storage apparatus according to claim 1, wherein endurance of the second memory line is higher than endurance of the plurality of first memory lines.

6. The storage apparatus according to claim 1, wherein the control unit assigns, to the first memory line in the unassigned state, an address assigned to a first memory line next to the first memory line in the unassigned state and puts the next first memory line into the unassigned state, depending on the plurality of first count values.

7. A method for controlling a storage apparatus, the method comprising:
determining, by a computer, on the basis of an address whether a write access to a physical memory including a plurality of first memory lines and a second memory line which is assigned one of consecutive addresses is a write access to one of the plurality of first memory lines or a write access to the second memory line, a part of the plurality of first memory lines being assigned the consecutive addresses and a rest of the plurality of first memory lines being put into an unassigned state in which no address is assigned;
finding, by the computer, a plurality of first count values indicative of numbers of times the plurality of first memory lines are written and a second count value indicative of a number of times the second memory line is written; and
using, by the computer, when a total sum of the plurality of first count values and the second count value exceeds a determined threshold, a first memory line in the unassigned state for swapping the address assigned to the second memory line with one of the addresses assigned to part of the first memory lines.

8. An information processing system comprising:
a storage apparatus; and
an information processing apparatus which writes data to the storage apparatus,
the storage apparatus including:
a physical memory including a plurality of first memory lines and a second memory line which is assigned one of consecutive addresses, a part of the plurality of first memory lines being assigned the consecutive addresses and a rest of the plurality of first memory lines being put into an unassigned state in which no address is assigned;
a determination unit which determines on the basis of an address whether a write access from the information processing apparatus to the physical memory is a write access to one of the plurality of first memory lines or a write access to the second memory line;
a counting unit which finds a plurality of first count values indicative of numbers of times the plurality of first memory lines are written and a second count value indicative of a number of times the second memory line is written; and
a control unit which uses, when a total sum of the plurality of first count values and the second count value exceeds a determined threshold, a first memory line in the unassigned state for swapping the address assigned to the second memory line with one of the addresses assigned to the part of the first memory lines.
